(19) United States
(12) Patent Application Publication
(10) Pub. No.: US 2024/0222112 A1
(43) Pub. Date: Jul. 4, 2024

(54) SUBSTRATE PROCESSING METHOD, METHOD OF MANUFACTURING SEMICONDUCTOR DEVICE, SUBSTRATE PROCESSING APPARATUS AND NON-TRANSITORY COMPUTER-READABLE RECORDING MEDIUM

(71) Applicant: Kokusai Electric Corporation, Tokyo (JP)

(72) Inventors: Naonori AKAE, Toyama (JP); Tomiyuki SHIMIZU, Toyama (JP); Takashi OZAKI, Toyama (JP)

(21) Appl. No.: 18/428,866

(22) Filed: Jan. 31, 2024

Related U.S. Application Data
(63) Continuation of application No. PCT/JP2021/033761, filed on Sep. 14, 2021.

(51) Int. Cl. H01L 21/02; C23C 16/40; C23C 16/455

(52) U.S. Cl. CPC H01L 21/0228; C23C 16/401; C23C 16/45527; H01L 21/02164; H01L 21/02216

(57) ABSTRACT

A technique is provided to perform: (a) forming a first film exerting a predetermined adhesive force on an inner surface of a concave structure formed on a surface of a substrate by supplying a first source gas to the substrate; and (b) forming a second film exerting an adhesive force smaller than that of the first film on the first film by supplying a second source gas to the substrate.

### CROSS REFERENCE TO RELATED APPLICATIONS

This application is a bypass continuation application of PCT International Application No. PCT/JP2021/033761, filed on Sep. 14, 2021, in the WIPO, the entire contents of which are hereby incorporated by reference.

### TECHNICAL FIELD

The present disclosure relates to a substrate processing method, a method of manufacturing a semiconductor device, a substrate processing apparatus and a non-transitory computer-readable recording medium.

### BACKGROUND

As a part of a manufacturing process of a semiconductor device, a process of forming a film on a surface of a substrate may be performed.

### SUMMARY

According to the present disclosure, there is provided a technique capable of reducing a stress generated between patterns formed on a surface of a substrate when filling an inside of a concave structure of the substrate with a film.

According to one embodiment of the present disclosure, there is provided a technique that includes: (a) forming a first film exerting a predetermined adhesive force on an inner surface of a concave structure formed on a surface of a substrate by supplying a first source gas to the substrate; and (b) forming a second film exerting an adhesive force smaller than that of the first film on the first film by supplying a second source gas to the substrate.

### BRIEF DESCRIPTION OF THE DRAWINGS

FIG. 1 is a diagram schematically illustrating a vertical cross-section of a vertical type process furnace 202 of a substrate processing apparatus preferably used in one or more embodiments of the present disclosure.

FIG. 2 is a diagram schematically illustrating a horizontal cross-section, taken along a line A—A shown in FIG. 1, of the vertical type process furnace 202 of the substrate processing apparatus preferably used in the embodiments of the present disclosure.

FIG. 3 is a block diagram schematically illustrating a configuration of a controller 121 and related components of the substrate processing apparatus preferably used in the embodiments of the present disclosure.

FIG. 4 is a diagram schematically illustrating a process sequence according to the embodiments of the present disclosure.

FIG. 5 is a diagram schematically illustrating a modified example of the process sequence according to the embodiments of the present disclosure.

FIG. 6 is a diagram schematically illustrating a partially enlarged view of a cross-section of a substrate with a concave structure on a surface thereof when the concave structure is filled by performing a film forming using a first source gas serving as a source gas.

FIG. 7 is a diagram schematically illustrating a partially enlarged view of a cross-section of the substrate with the concave structure on the surface thereof when the concave structure is filled by performing a film forming using a second source gas serving as the source gas.

FIG. 8 is a diagram schematically illustrating a partially enlarged view of a cross-section of the substrate with the concave structure on the surface thereof when the concave structure is filled by performing the film forming using the first source gas and the film forming using the second source gas in this order.

FIG. 9 is a diagram schematically illustrating a partially enlarged view of another cross-section of the substrate with the concave structure on the surface thereof when the concave structure is filled by performing the film forming using the first source gas and the film forming using the second source gas in this order.

FIG. 10 is a diagram schematically illustrating a relationship between a thickness of a film formed on the substrate and an adhesive force in the film.

### DETAILED DESCRIPTION

### <Embodiments of Present Disclosure>

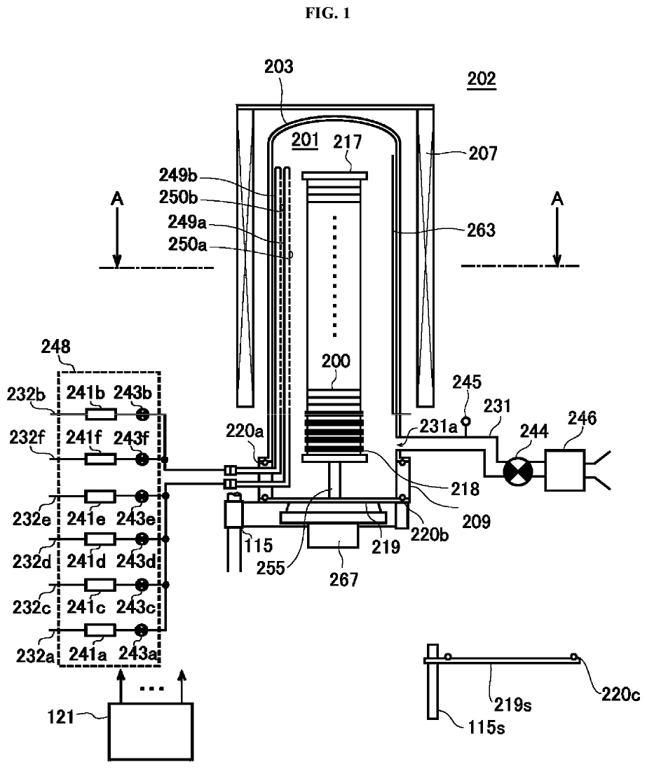

Hereinafter, one or more embodiments (also simply referred to as “embodiments”) of the technique of the present disclosure will be described in detail mainly with reference to FIGS. 1 to 4. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

As shown in FIG. 1, a substrate processing apparatus according to the present embodiments includes a vertical type process furnace (also simply referred to as a “process furnace”) 202. The process furnace 202 includes a heater 207 serving as a temperature regulator (which is a temperature adjusting structure, a heating structure or a heating device). The heater 207 is of a cylindrical shape, and is vertically installed while being supported by a support plate (not shown). The heater 207 also functions as an activator (also referred to as an “exciter”) capable of activating (or exciting) a gas by a heat.

A reaction tube 203 is provided in an inner side of the heater 207 to be aligned in a manner concentric with the heater 207. For example, the reaction tube 203 is made of a heat resistant material such as quartz (SiO₂) and silicon carbide (SiC). For example, the reaction tube 203 is of a cylindrical shape with a closed upper end and an open lower end. A manifold 209 is provided under the reaction tube 203 to be aligned in a manner concentric with the reaction tube 203. For example, the manifold 209 is made of a metal material such as stainless steel (SUS). For example, the manifold 209 is of a cylindrical shape with open upper and lower ends. An upper end portion of the manifold 209 is engaged with a lower end portion of the reaction tube 203 so as to support the reaction tube 203. An O-ring 220a serving as a seal is provided between the manifold 209 and the reaction tube 203. Similar to the heater 207, the reaction tube 203 is installed vertically. A process vessel (also referred to as a “reaction vessel”) is constituted mainly by the reaction tube 203 and the manifold 209. A process chamber 201 is provided in a hollow cylindrical portion of the process vessel. The process chamber 201 is configured to be capable of accommodating a plurality of wafers including a wafer 200 serving as a substrate. Hereinafter, the plurality of wafers including the wafer 200 may also be simply referred to as “wafers 200”. The wafer 200 is processed in the process chamber 201.

Nozzles 249a and 249b are provided in the process chamber 201 so as to penetrate a side wall of the manifold 209. The nozzle 249a serves as a first supplier (which is a first supply structure) and the nozzle 249b serves as a second supplier (which is a second supply structure). The nozzle 249a may also be referred to as a “first nozzle 249a”, and the nozzle 249b may also be referred to as a “second nozzle 249b”. For example, each of the nozzles 249a and 249b may be made of a heat resistant material such as quartz and silicon carbide (SiC). Gas supply pipes 232a and 232b are connected to the nozzles 249a and 249b, respectively. The nozzles 249a and 249b are different nozzles. The nozzles 249a and 249b are provided adjacent to each other.

Mass flow controllers (also simply referred to as “MFCs”) 24la and 241b serving as flow rate controllers (flow rate control structures) and valves 243a and 243b serving as opening/closing valves are sequentially installed at the gas supply pipes 232a and 232b, respectively, in this order from upstream sides to downstream sides of the gas supply pipes 232a and 232b in a gas flow direction. Gas supply pipes 232c, 232d, and 232e are connected to the gas supply pipe 232a at a downstream side of the valve 243a of the gas supply pipe 232a. A gas supply pipe 232f is connected to the gas supply pipe 232b at a downstream side of the valve 243b of the gas supply pipe 232b. MFCs 241c, 241d, 24le and 241f and valves 243c, 243d, 243c and 243f are sequentially installed at the gas supply pipes 232c, 232d, 232e and 232f, respectively, in this order from upstream sides to downstream sides of the gas supply pipes 232c, 232d, 232e and 232f in the gas flow direction. For example, each of the gas supply pipes 232a to 232f is made of a metal material such as stainless steel (SUS).

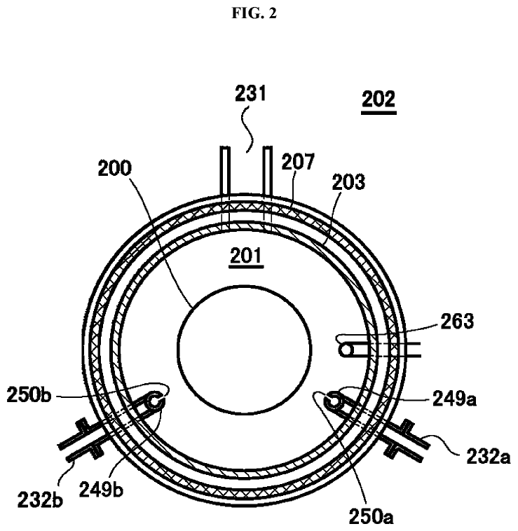

As shown in FIG. 2, each of the nozzles 249a and 249b is installed in an annular space provided between an inner wall of the reaction tube 203 and the wafers 200 when viewed from above, and extends upward from a lower portion toward an upper portion of the reaction tube 203 along the inner wall of the reaction tube 203 (that is, extends upward along a wafer arrangement direction). That is, each of the nozzles 249a and 249b is installed in a region that is located beside and horizontally surrounds a wafer arrangement region in which the wafers 200 are arranged (stacked) along the wafer arrangement direction. A plurality of gas supply holes 250a and a plurality of gas supply holes 250b are provided at side surfaces of the nozzles 249a and 249b, respectively. The gas supply holes 250a and the gas supply holes 250b are open toward a center of the wafer 200 when viewed from above, and are configured such that gases are capable of being supplied toward the wafers 200 via the gas supply holes 250a and the gas supply holes 250b. The gas supply holes 250a and the gas supply holes 250b are provided from the lower portion toward the upper portion of the reaction tube 203.

A first source gas serving as a source gas is supplied into the process chamber 201 through the gas supply pipe 232a provided with the MFC 241a and the valve 243a and the nozzle 249a.

An oxygen (O)-containing gas serving as an oxidizing gas is supplied into the process chamber 201 through the gas supply pipe 232b provided with the MFC 241b and the valve 243b and the nozzle 249b.

A second source gas serving as the source gas is supplied into the process chamber 201 through the gas supply pipe 232c provided with the MFC 241c and the valve 243c and the nozzle 249a.

A hydrogen (H)-containing gas serving as a reducing gas is supplied into the process chamber 201 through the gas supply pipe 232d provided with the MFC 241d and the valve 243d, the gas supply pipe 232a and the nozzle 249d. An oxidizing action cannot be obtained by the hydrogen-containing gas alone. However, in a substrate processing described later, by reacting the hydrogen-containing gas with the oxygen-containing gas under specific conditions, it is possible to generate an oxidizing species such as atomic oxygen (O). That is, the hydrogen-containing gas acts to improve an efficiency of an oxidation process. Therefore, the hydrogen-containing gas may be considered to be included in the oxidizing gas.

An inert gas is supplied into the process chamber 201 through the gas supply pipes 232e and 232f provided with the MFCs 24le and 241f and the valves 243c and 243f, respectively, the gas supply pipes 232a and 232b and the nozzles 249a and 249b. The inert gas acts as a purge gas, a carrier gas, a dilution gas and the like.

A first source gas supplier (which is a first source gas supply structure or a first source gas supply system) is constituted mainly by the gas supply pipe 232a, the MFC 24la and the valve 243a. A second source gas supplier (which is a second source gas supply structure or a second source gas supply system) is constituted mainly by the gas supply pipe 232c, the MFC 241c and the valve 243c.

An oxidizing gas supplier (which is an oxidizing gas supply structure or an oxidizing gas supply system) is constituted mainly by the gas supply pipe 232b, the MFC 241b and the valve 243b. A reducing gas supplier (which is a reducing gas supply structure or a reducing gas supply system) is constituted mainly by the gas supply pipe 232d, the MFC 241d and the valve 243d. The oxidizing gas supplier may further include the gas supply pipe 232d, the MFC 241d and the valve 243d. The oxidizing gas and the reducing gas are used as a reactive gas in the substrate processing described below. In the substrate processing, the reactive gas used to form a first film on the substrate (that is, the wafer 200) may also be referred to as a “first reactive gas”, and the reactive gas used to form a second film on the substrate (that is, the wafer 200) may also be referred to as a “second reactive gas”. Therefore, each or both of the oxidizing gas supplier and the reducing gas supplier may also be referred to as a reactive gas supplier (which is a reactive gas supply structure or a reactive gas supply system). The oxidizing gas supplier may also be referred to as a “first reactive gas supplier” (which is a first reactive gas supply structure or a first reactive gas supply system), and the reducing gas supplier may also be referred to as a “second reactive gas supplier” (which is a second reactive gas supply structure or a second reactive gas supply system).

An inert gas supplier (which is an inert gas supply structure or an inert gas supply system) is constituted mainly by the gas supply pipes 232e and 232f, the MFCs 241c and 241f and the valves 243c and 243f.

Each or both of the source gas and the reactive gas is also referred to as a film-forming gas, and each or both of the source gas supplier and the oxidizing gas supplier may also be referred to as a “film-forming gas supplier” (which is a film-forming gas supply structure or a film-forming gas supply system).

Any one or an entirety of the gas suppliers described above may be embodied as an integrated gas supply system 248 in which the components such as the valves 243a to 243f and the MFCs 24la through 241f are integrated. The integrated gas supply system 248 is connected to the respective gas supply pipes 232a to 232f. An operation of the integrated gas supply system 248 to supply various substances (various gases) to the gas supply pipes 232a to 232f, for example, operations such as an operation of opening and closing the valves 243a to 243f and an operation of adjusting flow rates of the gases through the MFCs 241a to 241f may be controlled by a controller 121 which will be described later. The integrated gas supply system 248 may be embodied as an integrated structure (integrated unit) of an all-in-one type or a divided type. The integrated gas supply system 248 may be attached to or detached from the components such as the gas supply pipes 232a to 232f on a basis of the integrated structure. Operations such as maintenance, replacement and addition for the integrated gas supply system 248 may be performed on a basis of the integrated structure.

An exhaust port 23la through which an inner atmosphere of the process chamber 201 is exhausted is provided at a lower side wall of the reaction tube 203. The exhaust port 23la may be provided so as to extend upward from the lower portion toward the upper portion of the reaction tube 203 along a side wall of the reaction tube 203 (that is, along the wafer arrangement region). An exhaust pipe 231 is connected to the exhaust port 23la. A vacuum pump 246 serving as a vacuum exhaust apparatus is connected to the exhaust pipe 231 through a pressure sensor 245 and an APC (Automatic Pressure Controller) valve 244. The pressure sensor 245 serves as a pressure detector (pressure detection structure) to detect an inner pressure of the process chamber 201, and the APC valve 244 serves as a pressure regulator (pressure adjusting structure). With the vacuum pump 246 in operation, the APC valve 244 may be opened or closed to perform a vacuum exhaust operation of the process chamber 201 or stop the vacuum exhaust operation. With the vacuum pump 246 in operation, the inner pressure of the process chamber 201 may be adjusted by adjusting an opening degree of the APC valve 244 based on pressure information detected by the pressure sensor 245. An exhauster (which is an exhaust structure or an exhaust system) is constituted mainly by the exhaust pipe 231, the APC valve 244 and the pressure sensor 245. The exhauster may further include the vacuum pump 246.

A seal cap 219 serving as a furnace opening lid capable of airtightly scaling (or closing) a lower end opening of the manifold 209 is provided under the manifold 209. For example, the scal cap 219 is made of a metal material such as SUS, and is of a disk shape. An O-ring 220b serving as a seal is provided on an upper surface of the seal cap 219 so as to be in contact with the lower end of the manifold 209. A rotator 267 configured to rotate a boat 217 described later is provided under the seal cap 219. A rotating shaft 255 of the rotator 267 is connected to the boat 217 through the seal cap 219. As the rotator 267 rotates the boat 217, the wafers 200 accommodated in the boat 217 are rotated. The seal cap 219 is elevated or lowered in the vertical direction by a boat elevator 115 serving as an elevating structure provided outside the reaction tube 203. The boat elevator 115 serves as a transfer device (which is a transfer structure or a transfer system) capable of transferring (loading) the wafers 200 into the process chamber 201 and capable of transferring (unloading) the wafers 200 out of the process chamber 201 by elevating and lowering the seal cap 219.

A shutter 219s serving as a furnace opening lid capable of airtightly sealing (or closing) the lower end opening of the manifold 209 is provided under the manifold 209. The shutter 219s is configured to close the lower end opening of the manifold 209 when the seal cap 219 is lowered by the boat elevator 115 and the boat 217 is unloaded out of the process chamber 201. For example, the shutter 219s is made of a metal material such as SUS, and is of a disk shape. An O-ring 220c serving as a seal is provided on an upper surface of the shutter 219s so as to be in contact with the lower end of the manifold 209. An opening and closing operation of the shutter 219s such as an elevation operation and a rotation operation is controlled by a shutter opener/closer (which is a shutter opening/closing structure) 115s.

The boat 217 (which is a substrate support or a substrate retainer) is configured such that the wafers 200 (for example, 25 wafers to 200 wafers) are accommodated (or supported) in the vertical direction in the boat 217 while the wafers 200 are horizontally oriented with their centers aligned with one another with a predetermined interval therebetween in a multistage manner. That is, the wafers 200 are arranged in a direction perpendicular to a surface of the wafer 200. For example, the boat 217 is made of a heat resistant material such as quartz and SiC. For example, a plurality of heat insulation plates 218 made of a heat resistant material such as quartz and SiC are supported at a lower portion of the boat 217 in a multistage manner.

A temperature sensor 263 serving as a temperature detector is installed in the reaction tube 203. A state of electric conduction to the heater 207 is adjusted based on temperature information detected by the temperature sensor 263 such that a desired temperature distribution of an inner temperature of the process chamber 201 can be obtained. The temperature sensor 263 is provided along the inner wall of the reaction tube 203.

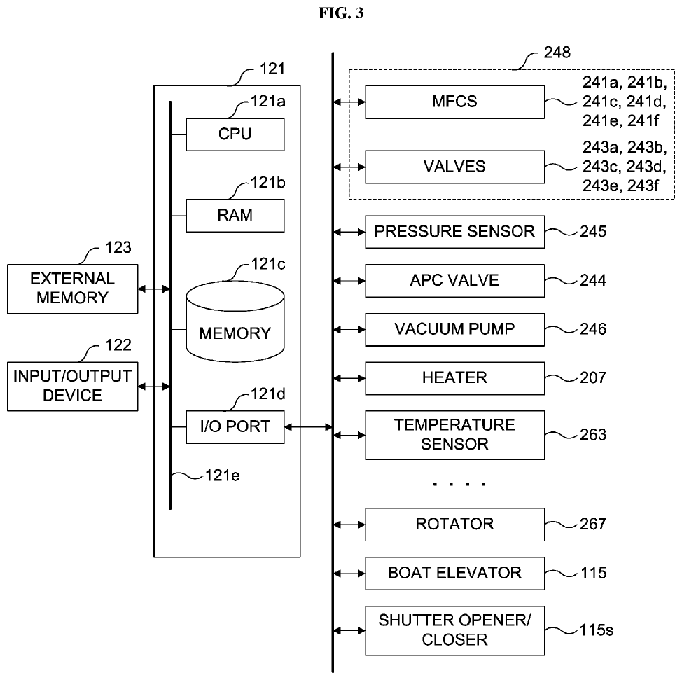

As shown in FIG. 3, the controller 121 serving as a control device (control structure) is constituted by a computer including a CPU (Central Processing Unit) 121a, a RAM (Random Access Memory) 121b, a memory 121c and an I/O port 121d. The RAM 121b, the memory 121c and the I/O port 121d may exchange data with the CPU 121a through an internal bus 121c. For example, an input/output device 122 constituted by a component such as a touch panel is connected to the controller 121. Further, the controller 121 is configured such that an external memory 123 can be connected to the controller 121.

The memory 121c is configured by a component such as a flash memory, a hard disk drive (HDD) and a solid state drive (SSD). For example, a control program configured to control an operation of the substrate processing apparatus and a process recipe containing information on sequences and conditions of a substrate processing described later may be readably stored in the memory 121c. The process recipe is obtained by combining steps (sequences or processes) of the substrate processing described later such that the controller 121 can execute the steps to acquire a predetermined result, and functions as a program. Hereinafter, the process recipe and the control program may be collectively or individually referred to as a “program”. In addition, the process recipe may also be simply referred to as a “recipe”. Thus, in the present specification, the term “program” may refer to the recipe alone, may refer to the control program alone or may refer to both of the recipe and the control program. The RAM 121b functions as a memory area (work arca) where a program or data read by the CPU 12la is temporarily stored.

The I/O port 121d is connected to the components described above such as the MFCs 24la to 241f, the valves 243a to 243f, the pressure sensor 245, the APC valve 244, the vacuum pump 246, the temperature sensor 263, the heater 207, the rotator 267, the boat elevator 115 and the shutter opener/closer 115s.

The CPU 12la is configured to read the control program from the memory 121c and execute the read control program. In addition, the CPU 12la is configured to read the recipe from the memory 121c, for example, in accordance with an operation command inputted from the input/output device 122. In accordance with the contents of the read recipe, the CPU 121a may be configured to be capable of controlling various operations such as flow rate adjusting operations for various substances (various gases) by the MFCs 241a to 241f, opening and closing operations of the valves 243a to 243f, an opening and closing operation of the APC valve 244, a pressure regulating operation (pressure adjusting operation) by the APC valve 244 based on the pressure sensor 245, a start and stop operation of the vacuum pump 246, a temperature adjusting operation by the heater 207 based on the temperature sensor 263, an operation of adjusting a rotation and a rotation speed of the boat 217 by the rotator 267, an elevating and lowering operation of the boat 217 by the boat elevator 115 and an opening and closing operation of the shutter 219s by the shutter opener/closer 115s.

The controller 121 may be embodied by installing the above-described program written and stored in the external memory 123 into the computer. For example, the external memory 123 may include a magnetic disk such as a hard disk drive (HDD), an optical disk such as a CD, a magneto-optical disk such as an MO and a semiconductor memory such as a USB memory and a solid state drive (SSD). The memory 121c or the external memory 123 may be embodied by a non-transitory computer readable recording medium. Hereafter, the memory 121c and the external memory 123 may be collectively or individually referred to as a “recording medium”. Thus, in the present specification, the term “recording medium” may refer to the memory 121c alone, may refer to the external memory 123 alone or may refer to both of the memory 121c and the external memory 123. Instead of the external memory 123, a communication interface such as the Internet and a dedicated line may be used for providing the program to the computer.

### (2) Substrate Processing

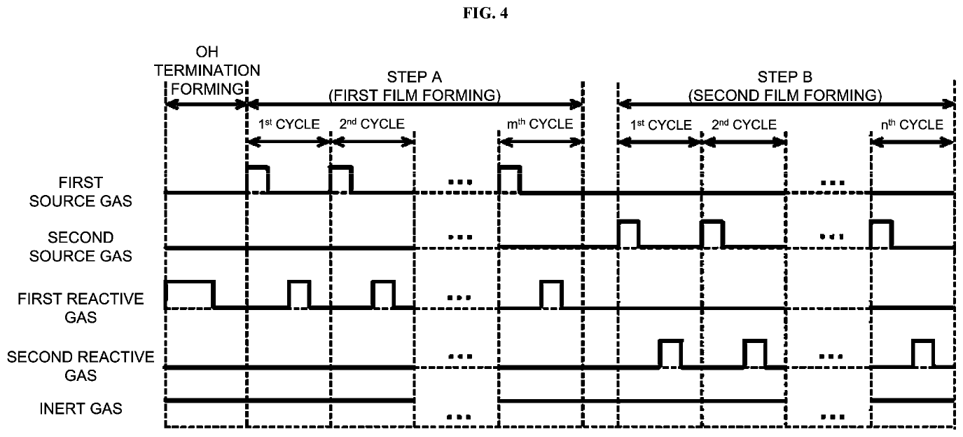

Hereinafter, an exemplary process sequence of the substrate processing (film forming process) of forming a film inside a concave structure so as to fill the concave structure provided on the surface of the wafer 200 serving as the substrate will be described mainly with reference to FIG. 4. The film forming process serves as a part of a manufacturing process of a semiconductor device, and is performed by using the substrate processing apparatus described above. In the following descriptions, the operations of components constituting the substrate processing apparatus are controlled by the controller 121.

An inner surface of the concave structure provided on the surface of the wafer 200 is constituted by side surfaces facing each other (that is, mutually facing side surfaces) and a bottom surface. The concave structure is of a so-called tapered shape in which a distance between the side surfaces at a lower portion of the concave structure is shorter (narrower) than a distance between the side surfaces at an upper portion of the concave structure.

The process sequence shown in FIG. 4 may include: a step A of forming the first film exerting a predetermined adhesive force on the inner surface of the concave structure by supplying the first source gas to the wafer 200 with the concave structure formed on the surface thereof; and a step B of forming the second film exerting an adhesive force smaller than that of the first film on the first film by supplying the second source gas to the wafer 200.

In the step A, a cycle wherein a step of supplying the first source gas and a step of supplying the first reactive gas are performed non-simultaneously is performed a predetermined number of times (m times, where m is an integer equal to or greater than 1).

In the step B, a cycle wherein a step of supplying the second source gas and a step of supplying the second reactive gas are performed non-simultaneously is performed a predetermined number of times (n times, where n is an integer equal to or greater than 1).

In the present specification, the process sequence described above may be illustrated as follows. Process sequences of modified examples and other embodiments, which will be described later, will be also represented in the same manner.

(First source gas →First reactive gas)×m →(Second source gas →Second reactive gas)×n

In the present specification, the term “wafer” may refer to “a wafer itself”, or may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, or may refer to “a surface of a predetermined layer (or a predetermined film) formed on a wafer”. Thus, in the present specification, “forming a predetermined layer (or a film) on a wafer” may refer to “forming a predetermined layer (or a film) directly on a surface of a wafer itself”, or may refer to “forming a predetermined layer (or a film) on a surface of another layer (or another film) formed on a wafer”. In the present specification, the terms “substrate” and “wafer” may be used as substantially the same meaning.

### <Wafer Charging Step and Boat Loading Step>

The wafers 200 are charged (transferred) into the boat 217 (wafer charging step). Then, the shutter 219s is moved by the shutter opener/closer 115s to open the lower end opening of the manifold 209 (shutter opening step). Thereafter, as shown in FIG. 1, the boat 217 supporting the wafers 200 is elevated by the boat elevator 115 and loaded (transferred) into the process chamber 201 (boat loading step). With the boat 217 loaded, the seal cap 219 airtightly seals the lower end of the manifold 209 via the O-ring 220b.

### <Pressure Adjusting Step and Temperature Adjusting Step>

The vacuum pump 246 vacuum-exhausts (decompresses and exhausts) the inner atmosphere of the process chamber 201 (that is, a space in which the wafers 200 are accommodated) such that the inner pressure of the process chamber 201 reaches and is maintained at a desired pressure (vacuum degree) (pressure adjusting step). When the vacuum pump 246 vacuum-exhausts the inner atmosphere of the process chamber 201, the inner pressure of the process chamber 201 is measured by the pressure sensor 245, and the APC valve 244 is feedback-controlled based on the pressure information detected by the pressure sensor 245. In addition, the heater 207 heats the process chamber 201 such that a temperature of the wafer 200 in the process chamber 201 reaches and is maintained at a process temperature (temperature adjusting step). When the heater 207 heats the process chamber 201, the state of the electric conduction to the heater 207 is feedback-controlled based on the temperature information detected by the temperature sensor 263 such that a desired temperature distribution of the inner temperature of the process chamber 201 can be obtained. In addition, a rotation of the wafer 200 is started by the rotator 267. The vacuum pump 246 continuously vacuum-exhausts the inner atmosphere of the process chamber 201, the heater 207 continuously heats the wafer 200 in the process chamber 201 and the rotator 267 continuously rotates the wafer 200 until at least a processing of the wafer 200 is completed.

### <OH Termination Forming Step>

In the present step, the first reactive gas is supplied (pre-flowed) to the wafer 200 in the process chamber 201.

Specifically, the valve 243b is opened such that the first reactive gas is supplied into the gas supply pipe 232b. A flow rate of the first reactive gas supplied into the gas supply pipe 232b is adjusted by the MFC 241b. Then, the first reactive gas whose flow rate is adjusted is supplied into the process chamber 201 through the nozzle 249b, and is exhausted through the exhaust port 23la. Thereby, the first reactive gas is supplied to the wafer 200 (first reactive gas supply step). In the present step, the valves 243e and 243f are opened such that the inert gas is supplied into the process chamber 201 through each of the nozzles 249a and 249b. Alternatively, the inert gas may not be supplied in the present step.

For example, the process conditions of the present step are as follows:
A process temperature: from 400° ° C. to 900° C., preferably from 600° ° C. to 700° C.;
A process pressure: from 0.1 Torr to 30 Torr, preferably from 0.2 Torr to 20 Torr;
A supply flow rate of the first reactive gas: from 0.1 slm to 20 slm, preferably from 5 slm to 12 slm;
A supply time (time duration) of the first reactive gas: from 100 seconds to 1,000 seconds, preferably from 200 seconds to 1,000 seconds; and
A supply flow rate of the inert gas (for each gas supply pipe): from 0 slm to 3.0 slm.

In the present specification, a notation of a numerical range such as “from 400° C. to 900° ° C.” means that a lower limit and an upper limit are included in the numerical range. Therefore, for example, a numerical range “from 400° C. to 900° C.” means a range equal to or higher than 400° C. and equal to or less than to 900° C. The same also applies to other numerical ranges described in the present specification. Further, in the present specification, the process temperature refers to the temperature of the wafer 200 or the inner temperature of the process chamber 201, and the process pressure refers to the inner pressure of the process chamber 201. Further, when a supply flow rate of a gas is zero (0) slm, it refers to a case where the gas is not supplied. The same also applies to the following descriptions.

By performing the present step under the process conditions described above, it is possible to form a hydroxyl group termination (OH termination) over an entirety of the surface of the wafer 200. The OH termination existing on the surface of the wafer 200 functions as an adsorption site for the source gas, that is, an adsorption site for a molecule and an atom constituting the source gas in a film forming described later.

After the OH termination is formed, the valve 243b is closed to stop a supply of the first reactive gas into the process chamber 201. Then, the inner atmosphere of the process chamber 201 is vacuum-exhausted such that a substance such as a gaseous substance remaining in the process chamber 201 is removed from the process chamber 201. When vacuum-exhausting the inner atmosphere of the process chamber 201, the valves 243e and 243f are opened such that the inert gas is supplied into the process chamber 201 through the nozzles 249a and 249b. The inert gas supplied via the nozzles 249a and 249b acts as the purge gas, and thereby, an inside of the process chamber 201 is purged (purge step).

For example, the process conditions of the purge step are as follows:
A supply flow rate of the inert gas (for each gas supply pipe): from 0.5 slm to 10 slm; and
A supply time (time duration) of the inert gas: from 1 second to 30 seconds, preferably from 5 seconds to 20 seconds.

For example, as the inert gas, nitrogen (N₂) gas or a rare gas such as argon (Ar) gas, helium (He) gas, neon (Ne) gas and xenon (Xe) gas may be used. One or more of those may be used as the inert gas. The same also applies to the steps described below.

### <Step A: First Film Forming Step>

Thereafter, the following steps a1 and a2 are performed sequentially.

<Step a1>

In the present step, the first source gas is supplied to the wafer 200 in the process chamber 201.

Specifically, the valve 243a is opened such that the first source gas is supplied into the gas supply pipe 232a. A flow rate of the first source gas supplied into the gas supply pipe 232a is adjusted by the MFC 24la. Then, the first source gas whose flow rate is adjusted is supplied into the process chamber 201 through the nozzle 249a, and is exhausted through the exhaust port 23la. Thereby, the first source gas is supplied to the wafer 200 (first source gas supply step). In the present step, the valves 243e and 243f are opened such that the inert gas is supplied into the process chamber 201 through each of the nozzles 249a and 249b. Alternatively, the inert gas may not be supplied in the present step.

For example, the process conditions of the present step are as follows:
A process temperature: from 400° C. to 900° C., preferably from 600° C. to 700° C.;
A process pressure: from 0.1 Torr to 10 Torr, preferably from 0.2 Torr to 10 Torr;
A supply flow rate of the first source gas: from 0.01 slm to 1 slm, preferably from 0.1 slm to 0.5 slm;
A supply time (time duration) of the first source gas: from 1 second to 100 seconds, preferably from 15 seconds to 20 seconds; and
A supply flow rate of the inert gas (for each gas supply pipe): from 0 slm to 10.0 slm.

For example, by supplying a silane gas containing an amino group and an alkoxy group (which will be described later) serving as the first source gas to the wafer 200 under the process conditions described above, it is possible to desorb the amino group from silicon (Si) contained in the first source gas without desorbing the alkoxy group. In addition, silicon whose amino group is desorbed therefrom and whose alkoxy groups are maintained being bonded thereto can be adsorbed (chemically adsorbed) on the surface of the wafer 200. In other words, it is possible to adsorb silicon to some of adsorption sites on the surface of the wafer 200 in a state where alkoxy groups are respectively bonded to three bonding sites of silicon. In a manner described above, a first layer (that is, a silicon (Si)-containing layer) containing a component in which the alkoxy group is bonded to silicon can be formed on an outermost surface of the wafer 200.

Further, by performing the present step under the process conditions described above, it is possible to prevent the amino group desorbed from silicon contained in the first source gas from being adsorbed to the surface of the wafer 200. As a result, it is possible to prevent the first layer formed on the wafer 200 from containing the amino group desorbed from silicon contained in the first source gas. That is, it is possible to provide the first layer to be formed on the wafer 200 as a layer with a low content of the amino group and a small amount of impurities such as carbon (C) and nitrogen (N) derived from the amino group.

In the present step, by the alkoxy group bonded to silicon adsorbed on the surface of the wafer 200, that is, by filling (blocking) the bonding sites of silicon adsorbed on the surface of the wafer 200 with the alkoxy group bonded to the Si adsorbed on the surface of the wafer 200, it is possible to inhibit an adsorption of at least one among an atom and a molecule to silicon adsorbed on the surface of the wafer 200. Further, in the present step, the alkoxy group bonded to silicon adsorbed on the surface of the wafer 200 acts as a steric hindrance. Thereby, it is possible to inhibit the adsorption of at least one among the atom and the molecule to the adsorption site (OH termination) around silicon atoms adsorbed on the surface of the wafer 200. In addition, in the present step, it is possible to preserve the adsorption site (OH termination) around the silicon atoms adsorbed on the surface of the wafer 200.

In the present step, it is preferable to continuously supply the first source gas until an adsorption reaction (chemical adsorption reaction) of silicon to the surface of the wafer 200 is saturated. Even when the first source gas is continuously supplied in a manner described above, since the alkoxy group bonded to silicon acts as the steric hindrance, it is possible to adsorb silicon discontinuously to the surface of the wafer 200. Specifically, silicon can be absorbed onto the surface of the wafer 200 to a thickness of less than one atomic layer.

In a state where the adsorption reaction of silicon to the surface of the wafer 200 is saturated, the surface of the wafer 200 is covered with the alkoxy group bonded to silicon, and a portion of the surface of the wafer 200 preserves the adsorption site (OH termination) without being consumed. In the state where the adsorption reaction of silicon to the surface of the wafer 200 is saturated, a layer constituted by silicon adsorbed to the surface of the wafer 200 becomes a discontinuous layer with a thickness of less than one atomic layer.

After the first layer is formed, the valve 243a is closed to stop a supply of the first source gas into the process chamber 201. Then, a substance such as a gaseous substance remaining in the process chamber 201 is removed from the process chamber 201 (purge step) by substantially the same process procedures and the same process conditions as the purge step of the OH termination forming step.

As the first source gas, for example, a gas with a molecular structure in which the alkoxy group and the amino group are bonded to silicon serving as a primary element (main element) constituting the film formed on the wafer 200 may be used.

The alkoxy group may refer to a monovalent functional group containing a structure in which an alkyl group (R) is bonded to oxygen (O) atom and represented by a structural formula -OR. The alkoxy group (—OR) may include a group such as a methoxy group (—OMe), an ethoxy group (—OEt), a propoxy group (—OPr) and a butoxy group (—OBu). The alkoxy group is not limited to straight chain alkoxy groups described above. The alkoxy group may include a branched alkoxy group such as an isopropoxy group, an isobutoxy group, a secondary butoxy group and a tertiary butoxy group. Further, the alkyl group (—R) may include a group such as a methyl group (—Me), an ethyl group (—Et), a propyl group (—Pr) and a butyl group (—Bu). The alkyl group is not limited to straight chain alkyl groups described above. The alkyl group may include a branched alkyl group such as an isopropyl group, an isobutyl group, a secondary butyl group and a tertiary butyl group.

The amino group may refer to a monovalent functional group containing a structure in which hydrogen (H) is removed from one of ammonia (NH₃), a primary amine and a secondary amine and represented by one of structural formulas —NH₂, —NHR and —NRR′. In the structural formula, each of R and R′ represents the alkyl group such as the methyl group, the ethyl group, the propyl group and the butyl group. Each of R and R′ is not limited to the straight chain alkyl groups described above. Each of R and R′ may represent the branched alkyl group such as the isopropyl group, the isobutyl group, the secondary butyl group and the tertiary butyl group. R and R′ may be the same alkyl group or different alkyl groups. As the amino group, for example, a group such as a dimethylamino group (—N(CH₃)₂) and a diethylamino group (—N(C₂H₅)₂) may be exemplified.

As the first source gas, for example, a dialkylamino trialkoxysilane gas such as (dimethylamino) triethoxysilane ([(CH₃)₂N|Si(OC₂H₅)₃) gas, (diethylamino) triethoxysilane ([(C₂H₅)₂N|Si(OC₂H₅)₃) gas, (dimethylamino) trimethoxysilane ([(CH₃)₂N|Si(OCH₃)₃) gas and (diethylamino) trimethoxysilane ([(C₂H₅)₂N|Si(OCH₃)₃) may be used. The dialkylamino trialkoxysilane gas may be used as the silane gas containing the amino group and the alkoxy group. SiIicon contained in the gases exemplified above contains four bonding sites. Alkoxy groups (such as the methoxy group and the ethoxy group) are respectively bonded to three of the four bonding sites of silicon, and the amino group (such as the dimethylamino group and diethylamino group) is bonded to the remaining one of the four bonding sites of silicon. In a manner described above, as the first source gas, it is preferable to use an organic gas containing the amino group in its molecular structure. As the first source gas, one or more of the gases exemplified above may be used.

As the first source gas, for example, an aminosilane-based gas such as tetrakis (dimethylamino) silane (Si[N(CH₃)₂]₄, abbreviated as 4DMAS) gas, tris (dimethylamino) silane (Si[N(CH₃)_{2]3}H, abbreviated as 3DMAS) gas, bis (diethylamino) silane (Si[N(C₂H₅)_{2]2}H₂, abbreviated as BDEAS) gas, bis (tertiarybutylamino) silane (SiH2[NH(C₄H₉)]2, abbreviated as BTBAS) gas and (diisopropylamino) silane (SiH3[N(C₃H₇)₂], abbreviated as DIPAS) gas may be used. As the first source gas, one or more of the gases exemplified above may be used.

<Step a2>

In the present step, the oxygen-containing gas serving as the first reactive gas is supplied to the wafer 200 in the process chamber 201.

Specifically, the valve 243b is opened such that the first reactive gas is supplied into the gas supply pipe 232b. A flow rate of the first reactive gas supplied into the gas supply pipe 232b is adjusted by the MFC 241b. Then, the first reactive gas whose flow rate is adjusted is supplied into the process chamber 201 through the nozzle 249b, and is exhausted through the exhaust port 23la. Thereby, the first reactive gas is supplied to the wafer 200 (first reactive gas supply step). In the present step, the valves 243e and 243f are opened such that the inert gas is supplied into the process chamber 201 through each of the nozzles 249a and 249b. Alternatively, the inert gas may not be supplied in the present step.

For example, the process conditions of the present step are as follows:
A process pressure: from 0.1 Torr to 30 Torr, preferably from 0.2 Torr to 20 Torr;
A supply flow rate of the first reactive gas: from 0.1 slm to 20 slm, preferably from 5 slm to 12 slm;
A supply time (time duration) of the first reactive gas: from 1 second to 200 seconds, preferably from 150 seconds to 190 seconds; and
A supply flow rate of the inert gas (for each gas supply pipe): from 0 slm to 3.0 slm.

The other process conditions of the present step may be set to be substantially the same as those of the step al of supplying the first source gas.

By performing the present step under the process conditions described above, for example, it is possible to desorb the alkoxy group bonded to silicon contained in the first layer from the first layer. By supplying the oxidizing gas (oxygen-containing gas) serving as the first reactive gas to the wafer 200 under the process conditions described above, for example, it is possible to oxidize (modify) at least a portion of the first layer formed on the wafer 200. Thereby, it is possible to form a silicon oxide layer (SiO layer), that is, a layer containing silicon (Si) and oxygen (O) serving as a second layer. The second layer is provided as a layer free of the alkoxy group and the like, that is, a layer free of the impurities such as carbon (C). Further, as a result of an oxidation process using the oxygen-containing gas, a surface of the second layer is in an OH-terminated state, that is, a state in which the adsorption site is formed. In addition, the impurities such as carbon desorbed from the first layer constitute a gaseous substance such as carbon dioxide (CO2) and are discharged from the process chamber 201. Thereby, the second layer (SiO layer) becomes a layer containing less impurities such as carbon than the first layer (silicon-containing layer) formed in the step al.

After the second layer is formed, the valve 243b is closed to stop the supply of the first reactive gas into the process chamber 201. Then, a substance such as a gaseous substance remaining in the process chamber 201 is removed from the process chamber 201 (purge step) by substantially the same process procedures and the same process conditions as the purge step of the step al.

As the first reactive gas, for example, the oxygen-containing gas such as oxygen (O2) gas, ozone (O₃) gas, water vapor (H₂O) gas, hydrogen peroxide (H₂O₂) gas, nitric oxide (NO) gas, nitrous oxide (N₂O) gas, carbon monoxide (CO) gas, nitrogen dioxide (NO₂) gas and a plasma-excited O₂ gas (O₂*) may be used. As the first reactive gas, one or more of the gases exemplified above may be used.

### <Performing Predetermined Number of Times>

By performing the cycle wherein the step al and the step a2 described above are performed non-simultaneously (that is, in a non-synchronized manner) in this order a predetermined number of times (m times, wherein m is an integer equal to or greater than 1), it is possible to form a first SiO film of a predetermined composition and a predetermined thicknesses serving as the first film on the wafer 200. It is preferable that the cycle described above is repeatedly performed a plurality of times. That is, it is preferable that the cycle described above is repeatedly performed a plurality of times until a thickness of the first SiO film formed by stacking the second layer (SiO layer) reaches a desired thickness while a thickness of the second layer formed per each cycle is smaller than the desired thickness.

Further, in the step A, it is preferable that the first SiO film is formed while maintaining a state (film thickness) in which mutually facing portions of the first SiO film formed on the mutually facing side surfaces of the concave structure provided on the surface of the wafer 200 do not contact each other.

Further, in the step A, it is preferable that a ratio of the thickness of the first SiO film to a total thickness of the thickness of the first SiO film and a thickness of a second SiO film serving as the second film described later is set to be 50% or less.

Further, in the step A, it is preferable that the ratio of the thickness of the first SiO film to the total thickness of the thickness of the first SiO film and the thickness of the second SiO film serving as the second film described later is set to be 10% or more.

In addition, a step coverage of the first SiO film is set to be higher than a step coverage of the second SiO film serving as the second film described later. This is because, in the step al, as described above, the layer constituted by silicon adsorbed to the surface of the wafer 200 becomes the discontinuous layer with the thickness of less than one atomic layer in a state where the adsorption reaction of silicon contained in the first source gas to the surface of the wafer 200 is saturated. That is, in the step al, for example, regardless of whether it is a side surface near the upper portion of the concave structure of the wafer 200 or it is the lower portion (bottom) of the concave structure, the first layer is prevented from being formed with a non-uniform thickness of one atomic layer or more. Thereby, the first layer is formed as a layer of a uniform thickness with a sufficient step coverage. In such a case, in the step a2, for example, on the side surfaces near the upper portion of the concave structure of the wafer 200 and on the lower portion of the concave structure, it is possible to react the oxygen-containing gas with the first layer with the sufficient step coverage. As a result, it is possible to provide the first SiO film as a film with the sufficient step coverage.

Further, the first SiO film contains characteristics capable of maintaining an oxidation amount of a base in a more preferable state than the second SiO film serving as the second film described later. The reason why the oxidation amount of the base can be maintained in the more preferable state when forming the first SiO film than when forming the second SiO film is because the first layer is oxidized in the step a2 under the process conditions in which an oxidizing power is weaker than that in a step b2 described later. Specifically, this is because, in the step a2, a gas whose oxidizing power is weaker than that of the second reactive gas used in the step b2 described later is used as the first reactive gas. As a result, it is possible to sufficiently suppress an oxidation of the base, that is, the oxidation of the surface of the wafer 200 in contact with the first SiO film. By suppressing the oxidation of the surface of the wafer 200, it is possible to reduce effects of the oxidation, such as a deterioration of device characteristics.

<Step B: Second Film Forming Step>

Thereafter, the following steps b1 and b2 are performed sequentially.

<Step b1>

In the present step, the second source gas is supplied to the wafer 200 in the process chamber 201.

Specifically, the valve 243c is opened such that the second source gas is supplied into the gas supply pipe 232c. A flow rate of the second source gas supplied into the gas supply pipe 232c is adjusted by the MFC 241c. Then, the second source gas whose flow rate is adjusted is supplied into the process chamber 201 through the nozzle 249a, and is exhausted through the exhaust port 23la. Thereby, the second source gas is supplied to the wafer 200 (second source gas supply step). In the present step, the valves 243e and 243f are opened such that the inert gas is supplied into the process chamber 201 through each of the nozzles 249a and 249b. Alternatively, the inert gas may not be supplied in the present step.

For example, the process conditions of the present step are as follows:
A supply flow rate of the second source gas: from 0.01 slm to 1 slm, preferably from 0.1 slm to 0.5 slm; and
A supply time (time duration) of the second source gas: from 1 second to 100 seconds, preferably from 15 seconds to 20 seconds.

The other process conditions of the present step may be set to be substantially the same as those of the step al of supplying the first source gas.

For example, by supplying a chlorosilane-based gas described later serving as the second source gas to the wafer 200 under the process conditions described above, it is possible to form a silicon-containing layer containing chlorine (Cl) serving as a third layer on the outermost surface (serving as the base) of the wafer 200. The silicon-containing layer containing chlorine is formed by a physical adsorption or a chemical adsorption of a molecule of the chlorosilane-based gas onto the outermost surface of the wafer 200, a physical adsorption or a chemical adsorption of a molecule of a partially decomposed substance of the chlorosilane-based gas onto the outermost surface of the wafer 200, or a deposition of silicon due to a thermal decomposition of the chlorosilane-based gas onto the outermost surface of the wafer 200. The silicon-containing layer containing chlorine may be an adsorption layer (a physical adsorption layer or a chemical adsorption layer) of the molecule of the chlorosilane-based gas or the molecule of the partially decomposed substance of the chlorosilane-based gas, or may be a deposition layer of silicon containing chlorine. In addition, under the process conditions described above, the physical adsorption or the chemical adsorption of the molecule of the chlorosilane-based gas or the molecule of the partially decomposed substance of the chlorosilane-based gas may occur dominantly (preferentially) on the outermost surface of the wafer 200, and the deposition of silicon due to the thermal decomposition of the chlorosilane-based gas occurs slightly or almost not at all. That is, under the process conditions described above, the third layer (that is, the silicon-containing layer) contains an overwhelming number of adsorption layers (physical adsorption layers or chemical adsorption layers) of the molecule of the chlorosilane-based gas or the molecule of the partially decomposed substance of the chlorosilane-based gas, and contains a small number of deposition layers of silicon containing chorine, or contains almost no deposition layer of silicon containing chorine.

After the third layer is formed, the valve 243c is closed to stop a supply of the second source gas into the process chamber 201. Then, a substance such as a gaseous substance remaining in the process chamber 201 is removed from the process chamber 201 (purge step) by substantially the same process procedures and the same process conditions as the purge step of the step al.

As the second source gas, for example, a silane-based gas containing silicon as the primary element (main element) constituting the film formed on the wafer 200 may be used. As the silane-based gas, for example, a gas containing silicon and a halogen element, that is, a halosilane-based gas may be used. As the halogen element, for example, an element such as chlorine (Cl), fluorine (F), bromine (Br) and iodine (I) may be used. As the halosilane-based gas, for example, as described above, the chlorosilane-based gas containing silicon and chlorine may be used.

As the second source gas, for example, the chlorosilane-based gas such as tetrachlorosilane (SiCl₄, abbreviated as STC) gas, hexachlorodisilane (Si₂Cl₆, abbreviated as HCDS) gas, trichlorosilane (SiHCl₃, abbreviated as TCS) gas, dichlorosilane (SiH₂Cl₂, abbreviated as DCS) gas and monochlorosilane (SiH₃Cl, abbreviated as MCS) gas may be used. That is, as the second source gas, an inorganic gas free of the amino group in its molecular structure may be used. As the second source gas, one or more of the gases exemplified above may be used.

As the second source gas, for example, instead of or in addition to the chlorosilane-based gas, a fluorosilane-based gas such as tetrafluorosilane (SiF₄) gas and difluorosilane (SiH₂F₂) gas, a bromosilane-based gas such as tetrabromosilane (SiBr₄) gas and dibromosilane (SiH₂Br₂) gas, and an iodosilane-based gas such as tetraiodosilane (SiI₄, abbreviated as STI) gas and diiodosilane (SiH₂₁₂) gas may be used. As the second source gas, one or more of the gases exemplified above may be used.

<Step b2>

In the present step, the hydrogen-containing gas and the oxygen-containing gas are supplied to the wafer 200 in the process chamber 201 as the second reactive gas.

Specifically, the valves 243b and 243d are opened such that the oxygen-containing gas and the hydrogen-containing gas are supplied into the gas supply pipes 232b and 232d, respectively. Flow rates of the oxygen-containing gas and the hydrogen-containing gas supplied into the gas supply pipes 232b and 232d are adjusted by the MFCs 241b and 241d, respectively. Then, the oxygen-containing gas and the hydrogen-containing gas whose flow rates are adjusted are supplied into the process chamber 201 through the nozzles 249b and 249a to be mixed and react with each other, and is exhausted through the exhaust port 23la. Thereby, an oxidizing species containing oxygen but free of water vapor (H₂O) such as the atomic oxygen (O) generated by reacting the hydrogen-containing gas with the oxygen-containing gas is supplied to the wafer 200 (oxygen-containing gas and hydrogen-containing gas supply step). In the present step, the valves 243e and 243f are opened such that the inert gas is supplied into the process chamber 201 through each of the nozzles 249a and 249b. Alternatively, the inert gas may not be supplied in the present step.

For example, the process conditions of the present step are as follows:
A process pressure: less than an atmospheric pressure, preferably from 0.1 Torr to 20 Torr, more preferably from 0.2 Torr to 0.8 Torr;
A supply flow rate of the oxygen-containing gas: from 0.1 slm to 10 slm, preferably from 0.5 slm to 10 slm;
A supply flow rate of the hydrogen-containing gas: from 0.01 slm to 5 slm, preferably from 0.1 slm to 1.5 slm;
A supply time (time duration) of each of the oxygen-containing gas and the hydrogen-containing gas: from 1 second to 200 seconds, preferably from 15 seconds to 50 seconds; and
A supply flow rate of the inert gas (for each gas supply pipe): from 0 slm to 10 slm.

The other process conditions of the present step may be set to be substantially the same as those of the step al of supplying the first source gas.

By performing the present step under the process conditions described above, it is possible to oxidize (modify) at least a portion of the third layer formed on the wafer 200. Thereby, it is possible to form a silicon oxide layer (SiO layer), that is, a layer containing silicon (Si) and oxygen (O) serving as a fourth layer. When forming the fourth layer (SiO layer), the impurities such as chorine (Cl) contained in the third layer (silicon-containing layer) constitute a gaseous substance containing at least chorine in a modification reaction of the silicon-containing layer by the oxygen-containing gas and the hydrogen-containing gas, and are discharged from the process chamber 201. Thereby, the fourth layer is provided as a layer containing less impurities such as chorine than the third layer formed in the step b1. Further, as a result of the oxidation process using the oxygen-containing gas and the hydrogen-containing gas, a surface of the fourth layer is in an OH-terminated state, that is, a state in which the adsorption site is formed.

By supplying the oxygen-containing gas and the hydrogen-containing gas simultaneously or together into the process chamber 201 under the process conditions described above, the oxygen-containing gas and the hydrogen-containing gas are thermally activated (excited) and react in a heated and reduced pressure atmosphere in a non-plasma manner. Thereby, it is possible to generate the oxidizing species containing oxygen but free of the water vapor (H₂O) such as the atomic oxygen (O). Then, the oxidation process (modification process) described above is performed mainly by the oxidizing species. According to the oxidation process, it is possible to significantly improve the oxidizing power as compared with the step a2 described above in which the oxygen-containing gas is supplied alone. That is, by supplying the oxygen-containing gas and the hydrogen-containing gas simultaneously or by adding the hydrogen-containing gas to the oxygen-containing gas in a reduced pressure atmosphere, it is possible to obtain a significant effect of improving the oxidizing power as compared with a case where the oxygen-containing gas is supplied alone.

After the fourth layer is formed, the valves 243b and 243d are closed to stop a supply of the oxygen-containing gas and a supply of the hydrogen-containing gas into the process chamber 201. Then, a substance such as a gaseous substance remaining in the process chamber 201 is removed from the process chamber 201 (purge step) by substantially the same process procedures and the same process conditions as the purge step of the step al.

As the second reactive gas, that is, as the oxygen-containing gas and the hydrogen-containing gas (“the oxygen-containing gas+the hydrogen-containing gas”), for example, a gas such as “O₂ gas+hydrogen (H₂) gas”, “ozone (O₃) gas+H₂ gas”, “hydrogen peroxide (H₂O₂) gas+H₂ gas” and “water vapor (H₂O gas)+H₂ gas” may be used. In such a case, deuterium (²H₂) gas may be used instead of the H₂ gas serving as the hydrogen-containing gas. Further, in the present specification, a notation of two gases such as “O₂ gas+H₂ gas” means a mixed gas of the H₂ gas and the O₂ gas. When supplying a mixed gas, the two gases may be mixed (pre-mixed) in the gas supply pipe and then supplied into the process chamber 201, or the two gases may be separately supplied into the process chamber 201 through different gas supply pipes and mixed (post-mixed) within the process chamber 201. As the second reactive gas, one or more of the gases exemplified above may be used.

Further, in the present step, at least one among the oxygen-containing gas and the hydrogen-containing gas may be plasma-excited and supplied. For example, a plasma-excited O₂ gas (O₂*) and a non-plasma-excited H₂ gas (H₂*) may be supplied, a non-plasma-excited O₂ gas and a plasma-excited H₂ gas may be supplied, or the plasma-excited O₂ gas and the plasma-excited H₂ gas may be supplied.

### <Performing Predetermined Number of Times>

By performing the cycle wherein the step b1 and the step b2 described above are performed non-simultaneously (that is, in a non-synchronized manner) in this order a predetermined number of times (n times, wherein n is an integer equal to or greater than 1), it is possible to form a second SiO film of a predetermined composition and a predetermined thicknesses serving as the second film on the wafer 200. It is preferable that the cycle described above is repeatedly performed a plurality of times. That is, it is preferable that the cycle described above is repeatedly performed a plurality of times until a thickness of the second SiO film formed by stacking the fourth layer (SiO layer) reaches a desired thickness while a thickness of the fourth layer formed per each cycle is smaller than the desired thickness.

Further, in the step B, it is preferable that the second SiO film is formed until mutually facing portions of the second SiO film formed on the first SiO film come into at least partial contact with each other.

Further, in the step B, it is preferable that the second SiO film is formed until an entirety of the concave structure of the wafer 200 is filled with the first SiO film and the second SiO film.

<After-purge Step and Returning to Atmospheric Pressure Step>

After the step of forming the second SiO film of the desired thickness on the wafer 200 is completed, the inert gas serving as the purge gas is supplied into the process chamber 201 through each of the nozzles 249a and 249b, and then is exhausted through the exhaust port 231a. Thereby, the inner atmosphere of the process chamber 201 is purged with the purge gas. As a result, a substance such as a residual gas and reaction by-products remaining in the process chamber 201 is removed from the process chamber 201 (after-purge step). Thereafter, the inner atmosphere of the process chamber 201 is replaced with the inert gas (substitution by inert gas), and the inner pressure of the process chamber 201 is returned to the normal pressure (atmospheric pressure) (returning to atmospheric pressure step).

### <Boat Unloading Step and Wafer Discharging Step>

Thereafter, the seal cap 219 is lowered by the boat elevator 115 and the lower end of the manifold 209 is opened. Then, the boat 217 with the processed wafers 200 supported therein is unloaded (transferred) out of the reaction tube 203 through the lower end of the manifold 209 (boat unloading step). After the boat 217 is unloaded, the shutter 219s is moved such that the lower end opening of the manifold 209 is sealed by the shutter 219s through the O-ring 220c (shutter closing step). The processed wafers 200 are discharged (transferred) from the boat 217 after the boat 217 is unloaded out of the reaction tube 203 (wafer discharging step).

### (3) Effects According to Present Embodiments

According to the present embodiments, it is possible to obtain one or more of the following effects.

(a) By performing the step A of forming the first film exerting the predetermined adhesive force on the inner surface of the concave structure by supplying the first source gas to the wafer 200 with the concave structure formed on the surface thereof and the step B of forming the second film exerting the adhesive force smaller than that of the first film on the first film by supplying the second source gas to the wafer 200, it is possible to suppress an occurrence of phenomena such as a collapse and a deformation of a pattern formed on the surface of the wafer 200 (hereinafter, such phenomena may also be collectively referred to as a “pattern collapse”).

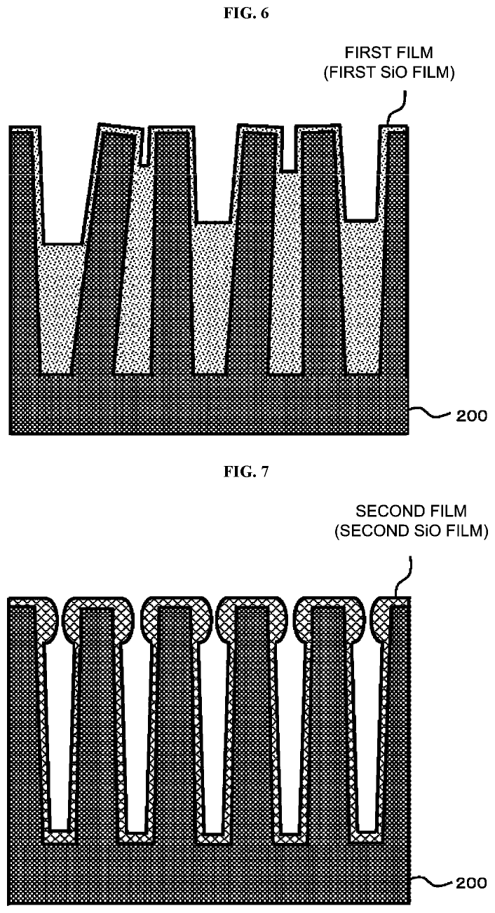

This is because, in a case where the first source gas alone is used as the source gas in the substrate processing described above and an inside of the concave structure is filled with the first SiO film alone exerting the adhesive force greater than that of the second film, the surfaces of the first SiO film tend to adhere to each other (attract each other) with a strong force as a forming of the first SiO film progresses when mutually facing surfaces of the first SiO film on the inner surface of the concave structure come into contact with each other. In a manner described above, the pattern collapse may occur due to an increase of a stress applied to the concave structure, that is, an attractive force generated between mutually facing inner surfaces of the concave structure (see FIG. 6).

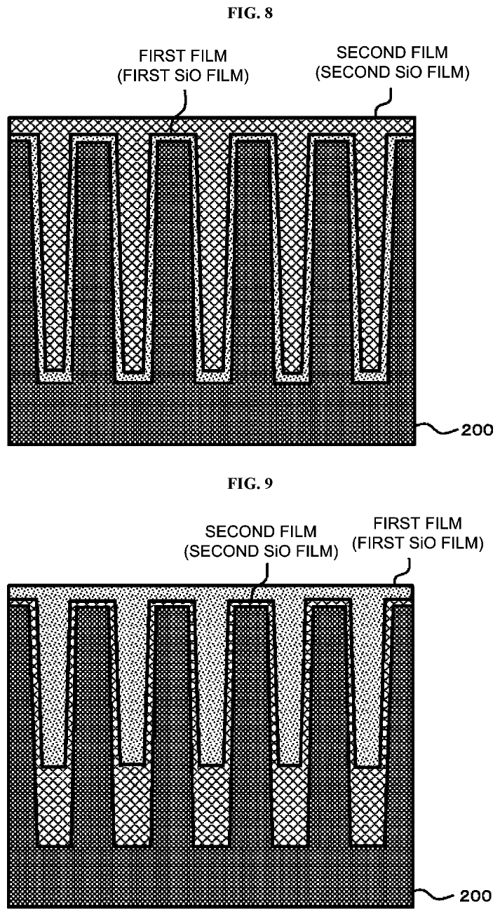

According to the present embodiments, it is possible to form the second SiO film exerting the adhesive force smaller than that of the first film on the first SiO film by combining a film forming by the first source gas and a film forming by the second source gas. Thereby, as compared with the case where the inside of the concave structure is filled with the first SiO film alone, it is possible to reduce the stress applied to the concave structure when the surfaces of the film formed on the inner surface of the concave structure come into contact with each other. As a result, it is possible to suppress an occurrence of the pattern collapse (see FIG. 8). According to the present embodiments, even when the second SiO film is formed in the step B until the entirety of the concave structure is filled with the first SiO film and the second SiO film, it is possible to suppress the occurrence of the pattern collapse.

In the present specification, the term “adhesive force” refers to an attractive force acting between molecules on a surface of a film mainly based on van der Waals force or the like. Further, the term “pattern collapse” refers to a phenomenon in which adjacent patterns come close to each other so as to lean against each other, and in some cases, the patterns break or peel off from the base.

(b) Even when the organic gas serving as the first source gas is supplied in the step A, it is possible to suppress the pattern collapse by supplying the inorganic gas serving as the second source gas in the step B.

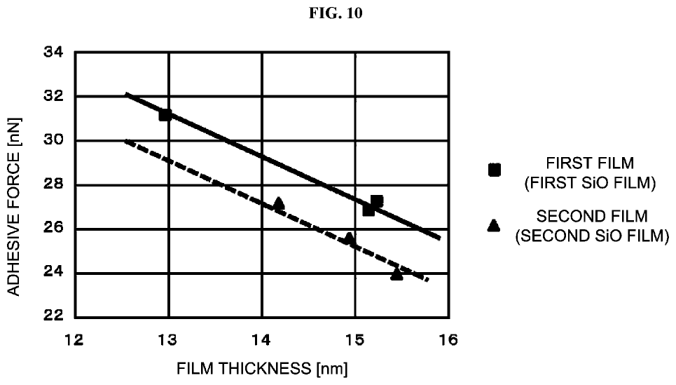

This is because, a molecular weight of the organic gas serving as the first source gas tends to be larger than a molecular weight of the inorganic gas serving as the second source gas, and accordingly, a molecular weight of a surface of the first SiO film is larger than a molecular weight of a surface of the second SiO film. The greater a molecular weight of each molecule constituting the surface of the film, the greater an adhesive force of the film. Thus, the adhesive force of the first SiO film is greater than the adhesive force of the second SiO film (see FIG. 10). According to the present embodiments, as described above, by combining the film forming by the first source gas and the film forming by the second source gas, it is possible to suppress the occurrence of the pattern collapse.

(c) In the step A, the first SiO film is formed while maintaining the state in which the mutually facing portions of the first SiO film respectively formed on the mutually facing side surfaces of the concave structure do not contact each other. Further, in the step B, the second SiO film is formed until the mutually facing portions of the second SiO film formed on the first SiO film come into at least partial contact with each other. That is, when filling the concave structure, a film contact is formed not by the first SiO film whose adhesive force is large but by the second SiO film whose adhesive force is small. Thereby, it is possible to reduce the stress applied to the concave structure as compared with the case where the portions of the first SiO film whose adhesive force is greater than the adhesive force of the second SiO film contact each other. As a result, it is possible to suppress the occurrence of the pattern collapse.

(d) It is possible to suppress the occurrence of the pattern collapse even when the concave structure on the surface of the wafer 200 is of the tapered shape in which the distance between the side surfaces at the lower portion of the concave structure is shorter than the distance between the side surfaces at the upper portion of the concave structure.

This is because, in both the first SiO film and the second SiO film, the thinner the thickness of the film, the greater the adhesive force of the film (see FIG. 10). In the present embodiments, when the concave structure is of the tapered shape as described above, the distance between the mutually facing side surfaces near the lower portion of the concave structure is shorter (narrower) than the distance between the mutually facing side surfaces at the upper portion of the concave structure. Therefore, as the forming of the first SiO film progresses, the portions of the first SiO film formed on the side surfaces near the lower portion of the concave structure may contact each other in a state where the first SiO film formed on the side surfaces near the lower portion of the concave structure is thinner than the first SiO film formed on the side surfaces near the upper portion of the concave structure, that is, in a state where the adhesive force is great. As a result, a large stress may be applied to the concave structure. As a result, the pattern collapse may be likely to occur starting from near the lower portion of the concave structure. According to the present embodiment, in the step A, the first SiO film is formed while maintaining the state in which the portions of the first SiO film formed on the mutually facing side surfaces of the concave structure do not contact each other. Thereby, it is possible to suppress the occurrence of the pattern collapse.

(c) By setting the ratio of the thickness of the first SiO film to the total thickness of the first SiO film and the second SiO film (that is, a thickness of a stacked SiO film) to be 50% or less, it is possible to prevent the surfaces of the first SiO film formed on the inner surface of the concave structure from coming into contact with each other. Thereby, it is possible to suppress the occurrence of the pattern collapse. When the ratio of the thickness of the first SiO film to the total thickness of the first SiO film and the second SiO film is higher than 50%, it may not be possible to prevent the contact between the surfaces of the first SiO film formed on the inner surface of the concave structure. In such a case, as a result, there is a high possibility that the pattern collapse will occur.

(f) By setting the step coverage of the first SiO film formed in the step A to be higher than the step coverage of the second SiO film formed in the step B, it is possible to suppress an occurrence of a void or a seam in the concave structure.

This is because, in the substrate processing described, in a case where the second source gas alone is used as the source gas and the inside of the concave structure is filled with the second SiO film alone whose step coverage is lower than the step coverage of the first SiO film, the second SiO film may locally grow thick near the upper portion of the concave structure, and the upper portion of the concave structure may be blocked before a filling the inside of the concave structure is completed. As a result, the void or the seam may occur within the concave structure (see FIG. 7).

According to the present embodiments, by combining the film forming by the first source gas and the film forming by the second source gas, the first SiO film whose step coverage is higher than the step coverage of the second SiO film is formed before the second SiO film is formed. Thereby, it is possible to suppress the occurrence of the void or the seam in the concave structure (see FIG. 8). According to the present embodiments, even when the second SiO film is formed until the entirety of the concave structure is filled with the first SiO film and the second SiO film in the step B, it is possible to suppress the occurrence of the void or the seam in the concave structure.

(g) In the step A, by using the gas containing the amino group in its molecular structure as the first source gas, it is possible to suppress the occurrence of the void or the seam in the concave structure.

This is because, in a case where the gas containing the amino group in its molecular structure is used as the source gas, as compared with a case where the gas free of the amino group in its molecular structure is used, it is possible to optimize a surface reaction between the molecule of the source gas and the surface of the wafer 200, and it is also possible to improve the step coverage of the film to be formed. According to the present embodiments, it is possible to suppress the occurrence of the void or the seam in the concave structure by supplying the first source gas containing the amino group in its molecular structure before supplying the second source gas free of the amino group in its molecular structure and forming the first SiO film whose step coverage is higher than the step coverage of the second SiO film before the second SiO film is formed.

(h) By setting the oxidizing power of the first reactive gas supplied in the step A to be smaller than the oxidizing power of the second reactive gas supplied in the step B, it is possible to suppress the oxidation of the base, that is, the oxidation of the surface of the wafer 200 in the step A.

Furthermore, in the step B, by setting the oxidizing power of the second reactive gas supplied in the step B to be greater than the oxidizing power of the first reactive gas supplied in the step A, it is possible to sufficiently oxidize the second SiO film formed in the step B. In addition, even when an insufficiently oxidized region remains in the first SiO film formed in the step A, it is possible to sufficiently oxidize such a region in the step B by utilizing the second reactive gas whose oxidizing power is high.

In a manner describe above, according to the present embodiments, it is possible to suppress the oxidation of the base, and it is also possible to reliably oxidize the first SiO film and the second SiO film.

Further, in a case where the first reactive gas whose oxidizing power is low is used as the reactive gas in each of the step A and the step B, even though it is possible to suppress the oxidation of the base, the first SiO film and the second SiO film may be oxidized insufficiently. In addition, in a case where the second reactive gas whose oxidizing power is high is used as the reactive gas in each of the step A and the step B, even though it is possible to sufficiently oxidize the first SiO film and the second SiO film, it may not be possible to suppress the oxidation of the basc.

(i) By setting the ratio of the thickness of the first SiO film to the total thickness of the first SiO film and the second SiO film (that is, the thickness of the stacked SiO film) to be 10% or more, it is possible to suppress the oxidation of the base due to the second reactive gas supplied in the step B. Further, it is possible to improve a step coverage of the stacked SiO film to be formed. When the ratio of the thickness of the first SiO film to the total thickness of the first SiO film and the second SiO film is lower than 10%, it may not be possible to suppress the oxidation of the base. Further, the step coverage of the stacked SiO film to be formed may be reduced.

### (4) Modified Examples

The process sequence of the substrate processing according to the embodiments described above may be modified as shown in the following modified examples. Unless otherwise described, process procedures and process conditions of each step of each of the modified examples may be substantially the same as the process procedures and the process conditions of each step of the embodiments described above.

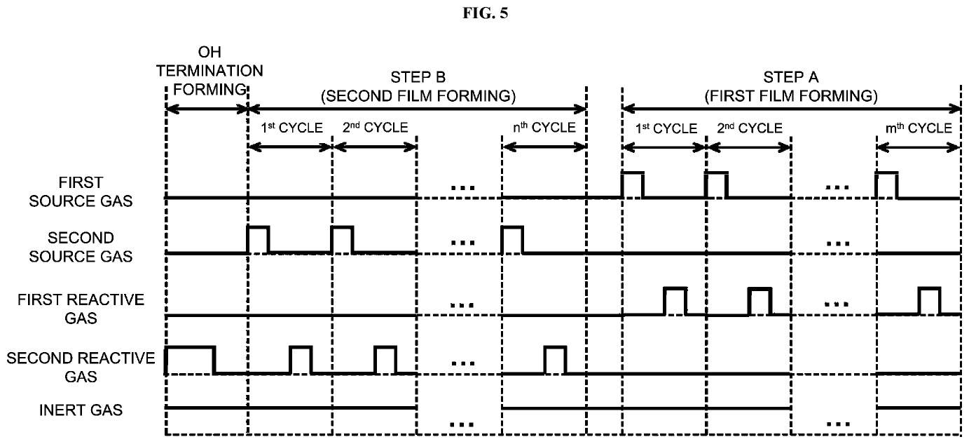

Instead of performing the step A and then performing the step B as in the process sequence in the embodiments described above, as in process sequences shown in FIG. 5 and below, the order in which each step is performed may be changed, and the step A may be performed after the step B. According to the present modified example, it is preferable that, in the step B, the second SiO film is formed until the mutually facing portions of the second SiO film formed on the mutually facing side surfaces of the concave structure provided on the surface of the wafer 200 come into contact with each other (that is, until the thickness of the second SiO film becomes sufficient for the mutually facing portions of the second SiO film to come into contact with each other). Further, it is more preferable that the second SiO film is formed until at least a portion of the lower portion of the concave structure is filled by the second SiO film whose adhesion force is smaller than that of the first SiO film.

$$( Second source gas \to Second reactive gas ) \times n \to ( First source gas \to First reactive gas ) \times m$$

Further, as in a gas supply sequence shown below, it is preferable to supply (pre-flow) the oxygen-containing gas and the hydrogen-containing gas to the wafer 200 as the second reactive gas before performing the step B. The process procedures in the present step may be substantially the same process procedures as the process procedures in the step b2 described above.

$$Second reactive gas \to ( Second source gas \to Second reactive gas ) \times n \to ( First source gas \to first reactive gas ) \times m$$

For example, the process conditions of the present step are as follows:

A process pressure: less than the atmospheric pressure, preferably from 0.1 Torr to 20 Torr, more preferably from 0.2 Torr to 0.8 Torr;

A supply flow rate of the oxygen-containing gas: from 0.1 slm to 10 slm, preferably from 0.5 slm to 10 slm;

A supply flow rate of the hydrogen-containing gas: from 0.01 slm to 5 slm, preferably from 0.1 slm to 1.5 slm;

A supply time (time duration) of each of the oxygen-containing gas and the hydrogen-containing gas: from 1 second to 200 seconds, preferably from 15 seconds to 50 seconds; and A supply flow rate of the inert gas (for each gas supply pipe): from 0 slm to 10 slm.

The other process conditions of the present step may be set to be substantially the same as those of the OH termination forming step of supplying the first source gas.

By performing the present step under the process conditions described above, it is possible to form the hydroxyl group termination (OH termination) over the entirety of the surface of the wafer 200. The OH termination existing on the surface of the wafer 200 functions as the adsorption site for the source gas, that is, the adsorption site for the molecule and the atom constituting the source gas in the film forming.

After the OH termination is formed, the valves 243b and 243d are closed to stop the supply of the oxygen-containing gas and the supply of the hydrogen-containing gas into the process chamber 201. Then, the substance such as the gaseous substance remaining in the process chamber 201 is removed from the process chamber 201 (purge step) by substantially the same process procedures and the same process conditions as the purge step of the step al.

In the step B, it is preferable that a ratio of the thickness of the second SiO film to the total thickness of the first SiO film serving as the first film and the second SiO film serving as the second film is set to be 90% or less. By setting such a ratio, it is possible to suppress the oxidation of the base by the second reactive gas supplied in the step B. Further, it is possible to improve the step coverage of the SiO film to be formed. When the ratio of the thickness of the second SiO film to the total thickness of the first SiO film and the second SiO film is higher than 90%, it may not be possible to suppress the oxidation of the base. Further, the step coverage of the stacked SiO film to be formed may be reduced.

In the step B, it is preferable that the ratio of the thickness of the second SiO film to the total thickness of the first SiO film serving as the first film and the second SiO film serving as the second film is set to be 50% or more. By setting such a ratio, it is possible to prevent the surfaces of the first SiO film formed on the inner surface of the concave structure from coming into contact with each other. Thereby, it is possible to suppress the occurrence of the pattern collapse. When the ratio of the thickness of the second SiO film to the total thickness of the first SiO film and the second SiO film is lower than 50%, it may not be possible to prevent the contact between the surfaces of the first SiO film formed on the inner surface of the concave structure. In such a case, as a result, there is a high possibility that the pattern collapse will occur.

According to the present modified example, in the step B, at least the lower portion of the concave structure is filled to some extent with the second SiO film serving as the second film whose adhesion force is smaller than that of the first SiO film serving as the first film, and then the step A is performed. Thereby, it is possible to suppress the pattern collapse which may occur starting from the lower portion of the concave structure (see FIG. 9).

### <Other Embodiments of Present Disclosure>

While the technique of the present disclosure is described in detail by way of the embodiments and the modified examples described above, the technique of the present disclosure is not limited thereto. The technique of the present disclosure may be modified in various ways without departing from the scope thereof.

For example, the embodiments described above are described by way of an example in which the SiO film (stacked SiO film) comprising the first SiO film and the second SiO film stacked is formed on the wafer 200 by sequentially performing the step A and step B. However, the technique of the present disclosure is not limited thereto. For example, the step A and the step B are performed in this order, and after the step B, the step A may be further performed to form the SiO film constituted by stacking the first SiO film, the second SiO film and the first SiO film on the wafer 200 in this order. Since the second step A (that is, a second execution of the step A) is further performed on the concave structure filled to some extent with the first SiO film and the second SiO film, it is possible to suppress the occurrence of the pattern collapse. Further, in the second execution of the step A, it is possible to fill the concave structure with the first SiO film whose step coverage is sufficient, and thereby, it is possible to more reliably suppress the occurrence of the void or the seam.

For example, the embodiments described above are described by way of an example in which the step A and the step B are each performed in the same process chamber 201 (that is, in-situ). However, the technique of the present disclosure is not limited thereto. For example, the step A and the step B may be performed in separate process chambers (that is, ex-situ). In such a case, it is preferable that the wafer 200 is not exposed to an atmosphere between the step A and the step B. Even in such a case, it is possible to obtain substantially the same effects as in the embodiments described above.

For example, the embodiments described above are described by way of an example in which the second SiO film is formed in the step B until the entirety of the concave structure is filled. However, the technique of the present disclosure is not limited thereto. For example, in the step B, the second SiO film may be formed to fill at least a portion of the concave structure. Even in such a case, it is possible to obtain substantially the same effects as in the embodiments described above.

For example, in each of the step A and the step B, instead of the SiO film, a silicon-based oxide film such as a silicon oxycarbide film (SiOC film), a silicon oxycarbonitride film (SiOCN film), a silicon oxynitride film (SiON film) a silicon boron oxynitride film (SiBON film) and a silicon boron oxycarbonitride film (SiBOCN film) may be formed. For example, in each of the step A and the step B, instead of the SiO film, a metal-based oxide film such as an aluminum oxide film (AlO film), a titanium oxide film (TiO film), a hafnium oxide film (HfO film) and a zirconium oxide film (ZrO film) may be formed.

For example, the embodiments and described above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of simultaneously processing one or several substrates is used to form the film. For example, the embodiments described above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

The process procedures and the process conditions of each process using the substrate processing apparatuses exemplified above may be substantially the same as those of the embodiments described above. Even in such a case, it is possible to obtain substantially the same effects as in the embodiments described above.

Further, the embodiments described above may be appropriately combined. For example, the process procedures and the process conditions of each combination thereof may be substantially the same as those of the embodiments described above.

### Examples

By performing the process sequence of the embodiments described above on a wafer with the concave structure formed on a surface thereof by using the substrate processing apparatus described above, the first SiO film and the second SiO film are formed so as to fill the inside of the concave structure. Thereby, a first sample is prepared. When preparing the first sample, the (dimethylamino) trimethoxysilane gas is used as the first source gas, the O₂ gas is used as the first reactive gas, the HCDS gas is used as the second source gas, and the “O₂ gas+hydrogen (H₂) gas” is used as the second reactive gas.

By performing the process sequence of the modified example described above on a wafer whose configuration is the same as that of the wafer used for preparing the first sample by using the substrate processing apparatus described above, the first SiO film and the second SiO film are formed so as to fill the inside of the concave structure. Thereby, a second sample is prepared. When preparing the second sample, the same gases as those used when preparing the first sample are used as the first source gas, the first reactive gas, the second source gas and second reactive gas, respectively.

By performing the step A alone of the process sequence of the embodiments described above on a wafer whose configuration is the same as that of the wafer used for preparing the first sample by using the substrate processing apparatus described above, the first SiO film is formed so as to fill the inside of the concave structure. Thereby, a third sample is prepared. When preparing the third sample, the same gases as those used when preparing the first sample are used as the first source gas and the first reactive gas, respectively. The other process conditions are set to be substantially the same as those of the step A of preparing the first sample.

By performing the step B alone of the process sequence of the embodiments described above on a wafer whose configuration is the same as that of the wafer used for preparing the first sample by using the substrate processing apparatus described above, the second SiO film is formed so as to fill the inside of the concave structure. Thereby, a fourth sample is prepared. When preparing the fourth sample, the same gases as those used when preparing the first sample are used as the second source gas and the second reactive gas, respectively. The other process conditions are set to be substantially the same as those of the step B of preparing the first sample.

Then, with respect to the first sample to the fourth sample, it was investigated whether the pattern collapse occurs and whether the oxidation of the base is suppressed.

The occurrence of the pattern collapse is determined by observing a cross-sectional TEM (transmission electron microscopy) image of the SiO film formed on the pattern. By observing the cross-sectional TEM image, it is confirmed that a lot of the pattern collapse occurs in the third sample in which the first source gas (organic gas) alone is supplied as the source gas than in the fourth sample in which the second source gas (inorganic gas) alone is supplied as the source gas. With respect to each of the third sample and the fourth sample, a histogram is created. A horizontal axis thereof represents a distance between the adjacent patterns (the distance between the side surfaces at the upper portion of the concave structure formed on the surface of the wafer), and a vertical axis thereof represents the number of the adjacent patterns that occur with each distance. By observing the histogram, it is confirmed that more variations in the distance between the adjacent patterns occur in the third sample than in the fourth sample. Therefore, when a standard deviation (nm) of the distance between the adjacent patterns is determined for each of the third sample and the fourth sample, the standard deviation of the third sample is greater than the standard deviation of the fourth sample. Based on such a result, the standard deviation of the fourth sample is used as a threshold to determine whether or not the pattern collapse occurs. When a standard deviation (nm) of the distance between the adjacent patterns is determined for each of the first sample and the second sample, the standard deviation of each of the first sample and the second sample is smaller than the standard deviation of the fourth sample. As a result, it is determined that the pattern collapse does not occur in the first sample and the second sample.

Whether the oxidation of the base is suppressed is determined by observing the cross-sectional TEM image of the SiO film formed on the patterns of each of the first sample to the fourth sample and measuring a thickness (nm) of the oxide film on the surface (that is, the base) of the wafer as an amount of the oxidation of the base. When measuring the thickness of the oxide film on the surface of the wafer of each of the first sample to the fourth sample, the thickness of the oxide film of the first sample is 1.2 (nm), the thickness of the oxide film of the second sample is 1.4 (nm), the thickness of the oxide film of the third sample is 0.6 (nm) and the thickness of the oxide film of fourth sample is 1.5 (nm). From such a result, it is determined whether or not the oxidation of the base is suppressed by using the thickness of the oxide film of the fourth sample (which is 1.5 (nm)), as a threshold. Since the thickness of the oxide film of each of the first sample and the second sample is thinner than the thickness of the oxide film of the fourth sample, it is determined that the oxidation of the base is suppressed in each of the first sample and the second sample.

What is claimed is:

1. A substrate processing method comprising:
(a) forming a first film exerting a predetermined adhesive force on an inner surface of a concave structure formed on a surface of a substrate by supplying a first source gas to the substrate; and
(b) forming a second film exerting an adhesive force smaller than that of the first film on the first film by supplying a second source gas to the substrate.

2. The substrate processing method of claim 1, wherein the inner surface of the concave structure comprises mutually facing side surfaces and a bottom surface,
wherein the first film is formed in (a) while maintaining a state in which mutually facing portions of the first film respectively formed on the mutually facing side surfaces are out of contact with each other, and
wherein the second film is formed in (b) until mutually facing portions of the second film formed on the first film come into at least partial contact with each other.

3. The substrate processing method of claim 1, wherein a cycle of supplying the first source gas and a first reactive gas is performed a predetermined number of times in (a) to form the first film, and a cycle of supplying the second source gas and a second reactive gas is performed a predetermined number of times in (b) to form the second film.

4. The substrate processing method of claim 3, wherein each of the first reactive gas and the second reactive gas comprises an oxidizing gas, and each of the first film and the second film comprises an oxide film.

5. The substrate processing method of claim 4, wherein an oxidizing power of the first reactive gas is set to be smaller than an oxidizing power of the second reactive gas.

6. The substrate processing method of claim 1, wherein a step coverage of the first film is set to be higher than a step coverage of the second film.

7. The substrate processing method of claim 1, wherein a molecular weight of the first source gas is set to be larger than a molecular weight of the second source gas.

8. The substrate processing method of claim 7, wherein the first source gas comprises an organic gas, and the second source gas comprises an inorganic gas.

9. The substrate processing method of claim 1, wherein the second film is formed in (b) until at least a portion of the concave structure is filled with the first film and the second film.

10. The substrate processing method of claim 9, wherein the second film is formed in (b) until an entirety of the concave structure is filled with the first film and the second film.

11. The substrate processing method of claim 1, wherein the inner surface of the concave structure comprises mutually facing side surfaces, and
wherein a distance between the mutually facing side surfaces at a lower portion of the concave structure is shorter than a distance between the mutually facing side surfaces at an upper portion of the concave structure.

12. The substrate processing method of claim 1, wherein each of the first source gas and the second source gas contains a molecular structure containing a predetermined element, and
wherein each of the first film and the second film comprises a film containing the predetermined element.

13. The substrate processing method of claim 12, wherein the predetermined element comprises silicon, and
wherein an amino group is bonded to one bonding site of an atom of the silicon contained in the first source gas and alkoxy groups are respectively bonded to remaining three bonding sites of the atom of the silicon.

14. The substrate processing method of claim 13, wherein, in (a), the first source gas is supplied to the substrate under conditions where: (i) the amino group is desorbed from the silicon without desorbing the alkoxy groups from the silicon; and (ii) the silicon whose amino group is desorbed therefrom but whose alkoxy groups are maintained being bonded thereto is adsorbed on the surface of the substrate.

15. The substrate processing method of claim 13, wherein the first source gas comprises a dialkylaminotrialkoxysilane gas.

16. The substrate processing method of claim 12, wherein the molecular structure of the second source gas further contains a halogen element bonded to the predetermined element.

17. The substrate processing method of claim 1, wherein (a) is further performed after (b) to form the first film on the second film.

18. A method of manufacturing a semiconductor device, comprising the substrate processing method of claim 1.

19. A substrate processing apparatus comprising:
a first source gas supplier through which a first source gas is supplied to a substrate;
a second source gas supplier through which a second source gas whose molecular structure is different from that of the first source gas is supplied to the substrate; and
a controller configured to be capable of controlling the first source gas supplier and the second source gas supplier to perform:
(a) forming a first film exerting a predetermined adhesive force on an inner surface of a concave structure formed on a surface of the substrate by supplying the first source gas to the substrate; and
(b) forming a second film exerting an adhesive force smaller than that of the first film on the first film by supplying the second source gas to the substrate.

20. A non-transitory computer-readable recording medium storing a program that causes a substrate processing apparatus, by a computer, to perform:
(a) forming a first film exerting a predetermined adhesive force on an inner surface of a concave structure formed on a surface of a substrate by supplying a first source gas to the substrate; and
(b) forming a second film exerting an adhesive force smaller than that of the first film on the first film by supplying a second source gas to the substrate.
